(19) United States
(12) Patent Application Publication
(10) Pub. No.: US 2026/0251694 A1
(43) Pub. Date: Aug. 27, 2026

(54) THERMAL DONOR QUANTITY PREDICTION METHOD AND APPARATUS USING LIFETIME OF SILICON WAFER

(71) Applicant: SK SILTRON CO., LTD., Gumi Si (KR)

(72) Inventor: Min Gyu PARK, Gumi-si (KR)

(21) Appl. No.: 19/169,265

(22) Filed: Apr. 3, 2025

(30) Foreign Application Priority Data
Feb. 25, 2025 (KR) 10-2025-0024208

(51) Int. Cl. G01R 31/28; G01R 27/02; H01L 21/66

(52) U.S. Cl. CPC G01R 31/2831; G01R 27/02; H10P 74/207

(57) ABSTRACT

Disclosed are a thermal donor quantity prediction method using the lifetime of a silicon wafer including measuring the lifetime and the thermal donor quantity of a sampling wafer before and after donor killing and comparing the same to acquire correlation data and acquiring the lifetime of a wafer to be inspected that is selected during a wafer production process before and after donor killing and predicting the thermal donor quantity based on the correlation data and a thermal donor quantity prediction apparatus that performs the method. It is possible to construct correlation data with a four-point probe and to predict the degree of generation of thermal donors in a non-destructive manner based on the correlation data, thereby reducing a decrease in production yield without wafer damage and improving thermal donor quantity prediction reliability while having high analysis capability for a front surface of a wafer.

### CROSS REFERENCE TO RELATED APPLICATION

This application claims priority under 35 U.S.C. § 119 to Korean Patent Application No. 10-2025-0024208, filed in Korea on 25 Feb. 2025, which is hereby incorporated in its entirety by references as if fully set forth herein.

### TECHNICAL FIELD

Embodiments relate to thermal donor inspection, and more particularly to a thermal donor quantity prediction method and apparatus using the lifetime of a silicon wafer capable of improving thermal donor quantity prediction reliability while having high analysis capability for a front surface of a wafer in a non-contact manner without wafer damage based on correlation data with a four-point probe.

### BACKGROUND

Generally, after cutting an ingot into the shape of a wafer, the waviness of the surface and the difference (taper) in wafer thickness occur, and a grinding process performed for planarization is called lapping.

After lapping, chemical etching is performed to mitigate the damage to the wafer, and the roughness of the wafer is reduced through this series of processes.

A thermal annealing process is required before a final polishing process. Unwanted charged interstitial oxygen complexes contained in silicon are called thermal donors. In order to remove the thermal donors and to stabilize resistivity of the wafer, annealing is performed at about 700° C., which is called donor killing.

At this time, manufacturers of silicon wafers or manufacturers that use the same to produce semiconductor devices monitor the degree of generation of thermal donors, which cause increased variation in product performance during production and increased defect rates, and feed back the results to a production process or recycle or discard produced wafers.

The monitoring method mainly uses a four-point probe with high measurement precision, which is a probe for surface resistance measurement with four probes. Usually, the spacing is 1 mm, and the probes are arranged linearly. In addition, there are a square type Hall probe in which probes are arranged in a forward direction and a high-temperature probe specially designed to withstand high temperatures.

The four-point probe is the most accurate tool for measurement of the surface resistance of a material. A method of measuring the degree of generation of thermal donors using the four-point probe is to measure specific resistance values of a wafer to be inspected before and after donor killing and to quantify the thermal donors using the difference between the values.

The thermal donor quantification method using the four-point probe has the advantage of enabling accurate quantification in terms of concentration, but the disadvantage of causing damage to the wafer surface due to the physical contact of the probe.

This disadvantage causes the wafer to be inspected to lose functionality as a product, which leads to a decrease in the overall production yield. Moreover, the four-point probe has a probe spacing of about 1 mm to 2 mm, which means that the four-point probe is relatively less efficient for analysis of the entire wafer.

### SUMMARY

Embodiments solve the above problems.

Embodiments provide a thermal donor quantity prediction method and apparatus using the lifetime of a silicon wafer capable of improving thermal donor quantity prediction reliability while having high analysis capability for a front surface of a wafer in a non-contact manner without wafer damage based on correlation data with a four-point probe.

In one embodiment, a thermal donor quantity prediction method using the lifetime of a silicon wafer includes measuring the lifetime and the thermal donor quantity of a sampling wafer before and after donor killing and comparing the same to acquire correlation data and acquiring the lifetime of a wafer to be inspected that is selected during a wafer production process before and after donor killing and predicting the thermal donor quantity based on the correlation data.

According to an exemplary embodiment, the thermal donor quantity prediction method may further include feeding back information of the predicted thermal donor quantity to the wafer production process to adjust the wafer production process if the predicted thermal donor quantity exceeds a preset threshold range.

According to an exemplary embodiment, the acquisition step may include a step of providing the sampling wafer, a first measurement step of measuring the lifetime and the resistance value of the sampling wafer before donor killing, a second measurement step of measuring the lifetime and the resistance value of the sampling wafer after donor killing, a step of calculating the thermal donor quantity based on the amount of change in the lifetime measured in the first measurement step and the second measurement step and the measured resistance value, and a step of comparing the lifetime change amount with the thermal donor quantity to generate correlation data.

According to an exemplary embodiment, the first measurement step may include a step of generating a first lifetime image map of a front surface of the sampling wafer before the donor killing, a first profiling step of profiling the lifetime corresponding to coordinate values of the front surface of the sampling wafer based on the first lifetime image map, and a first resistance value measurement step of measuring the resistance from a plurality of preset coordinate values among the coordinate values of the front surface of the sampling wafer before the donor killing.

According to an exemplary embodiment, the second measurement step may include a step of generating a second lifetime image map of the front surface of the sampling wafer after the donor killing, a second profiling step of profiling the lifetime corresponding to the coordinate values of the front surface of the sampling wafer based on the second lifetime image map, and a second resistance value measurement step of measuring the resistance from the plurality of preset coordinate values among the coordinate values of the front surface of the sampling wafer after the donor killing.

According to an exemplary embodiment, the sampling wafer used in the first measurement step and the sampling wafer used in the second measurement step may be the same.

According to an exemplary embodiment, the step of generating the correlation data may include predicting the thermal donor quantity according to the lifetime change amount from the plurality of the same preset coordinate values and comparing the predicted thermal donor quantity with the acquired thermal donor quantity to obtain the correlation data.

According to an exemplary embodiment, the thermal donor quantity prediction method may further include generating a correlation function between the predicted thermal donor quantity and the acquired thermal donor quantity based on the correlation data from the plurality of the same preset coordinate values after the step of generating the correlation data, wherein upon predicting the thermal donor quantity, the correlation function may be provided as a criterion for correcting the predicted thermal donor quantity.

According to an exemplary embodiment, the prediction step may include selecting an arbitrary wafer to be inspected during the wafer production process, acquiring the lifetime of the wafer to be inspected before and after donor killing, calculating the lifetime change amount based on the acquired lifetime, calculating the thermal donor quantity according to the lifetime change amount, and correcting the calculated thermal donor quantity based on the correlation function to estimate the thermal donor quantity.

In another embodiment, there is provided a computer-readable recording medium having a program for performing the thermal donor quantity prediction method recorded therein.

In yet another embodiment, a thermal donor quantity prediction apparatus using the lifetime of a silicon wafer includes a prediction criterion data unit configured to measure the lifetime and the thermal donor quantity of a sampling wafer before and after donor killing and to compare the same to acquire correlation criterion and a thermal donor prediction unit configured to acquire the lifetime of a wafer to be inspected that is selected during a wafer production process before and after donor killing and to predict the thermal donor quantity based on the correlation criterion.

According to an exemplary embodiment, the thermal donor prediction unit may feed back information of the predicted thermal donor quantity to the wafer production process to adjust the wafer production process if the predicted thermal donor quantity exceeds a preset threshold range.

According to an exemplary embodiment, the prediction criterion data unit may include a first donor killing portion configured to perform heat treatment on the sampling wafer at a preset temperature, a first non-contact lifetime measurement portion configured to acquire the lifetime of a front surface of the sampling wafer before and after heat treatment through the first donor killing portion, a surface resistance measurement portion configured to measure the resistance value from a plurality of preset coordinate values among coordinate values of the front surface of the sampling wafer before and after heat treatment through the donor killing portion, and a correlation data processing portion configured to receive data measured by the first non-contact lifetime measurement portion and data measured by the surface resistance measurement portion before and after the heat treatment, to convert the received data into data according to the thermal donor quantity, and to generate correlation data.

According to an exemplary embodiment, the sampling wafer used by the surface resistance measurement portion and the sampling wafer used by the first non-contact lifetime measurement portion may be the same.

According to an exemplary embodiment, the prediction criterion data unit may further include a correlation criterion generation portion configured to generate a correlation function based on the correlation data.

According to an exemplary embodiment, the prediction criterion data unit may further include a data learning processing portion configured to learn based on a database constituted by the correlation data and the correlation function.

According to an exemplary embodiment, the correlation data processing portion may be configured to receive the data measured by the first non-contact lifetime measurement portion before and after the heat treatment, to calculate the lifetime change amount, and to predict the thermal donor quantity based on the calculated lifetime change amount, may be configured to receive the data measured by the surface resistance measurement portion before and after the heat treatment, to calculate the resistance value change amount, and to calculate the thermal donor quantity based on the calculated resistance value change amount, and may be configured to generate correlation data between the predicted thermal donor quantity based on the lifetime change amount and the calculated thermal donor quantity based on the resistance value change amount.

According to an exemplary embodiment, if the correlation data between the predicted thermal donor quantity based on the lifetime change amount and the calculated thermal donor quantity based on the resistance value change amount is generated so as to correspond to a plurality of preset coordinate values among coordinate values of the front surface of the sampling wafer through the correlation data processing portion, the correlation criterion generation portion may generate a correlation function that includes the coordinate values of the front surface of the sampling wafer based on the correlation data.

According to an exemplary embodiment, the thermal donor prediction unit may include a second donor killing portion configured to perform heat treatment on an arbitrary wafer to be inspected at a preset temperature upon selecting the wafer to be inspected during a wafer production process, a second non-contact lifetime measurement portion configured to acquire the lifetime of a front surface of the wafer to be inspected before and after heat treatment through the second donor killing portion, and a thermal donor quantity prediction portion configured to receive the lifetime of the front surface of the wafer to be inspected before and after the heat treatment and the correlation function and to predict the thermal donor quantity of the wafer to be inspected.

According to an exemplary embodiment, the thermal donor quantity prediction portion may receive the lifetime of the front surface of the wafer to be inspected before and after the heat treatment, may calculate the lifetime change amount, may predict the thermal donor quantity based on the calculated lifetime change amount, and may correct the predicted thermal donor quantity based on the correlation function to finally predict the thermal donor quantity.

### BRIEF DESCRIPTION OF THE DRAWINGS

Arrangements and embodiments may be described in detail with reference to the following drawings in which like reference numerals refer to like elements and wherein:

FIG. 1 is an exemplary block diagram of a thermal donor quantity prediction apparatus using the lifetime of a silicon wafer according to an embodiment; and

FIGS. 2 and 3 are exemplary views illustrating the correlation between lifetime and thermal donor quantity.

### DESCRIPTION OF SPECIFIC EMBODIMENTS

Embodiments may be modified into many other forms, and the scope of the present disclosure should not be construed as being limited to the embodiments described below. The embodiments are provided to more fully explain the present disclosure to those skilled in the art.

In addition, the relational terms “first,” “second,” “above,” and “below” are used herein only to distinguish between one subject or element and another subject or element without necessarily requiring or involving any physical or logical relationship or sequence between such subjects or elements.

Hereinafter, a thermal donor quantity prediction method and apparatus using the lifetime of a silicon wafer according to embodiments will be described with reference to the accompanying drawings.

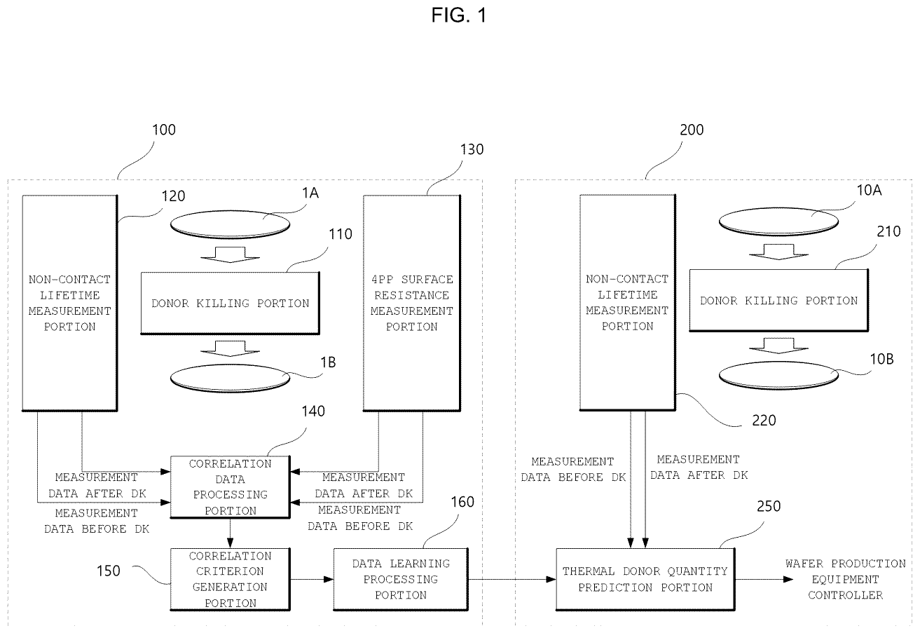

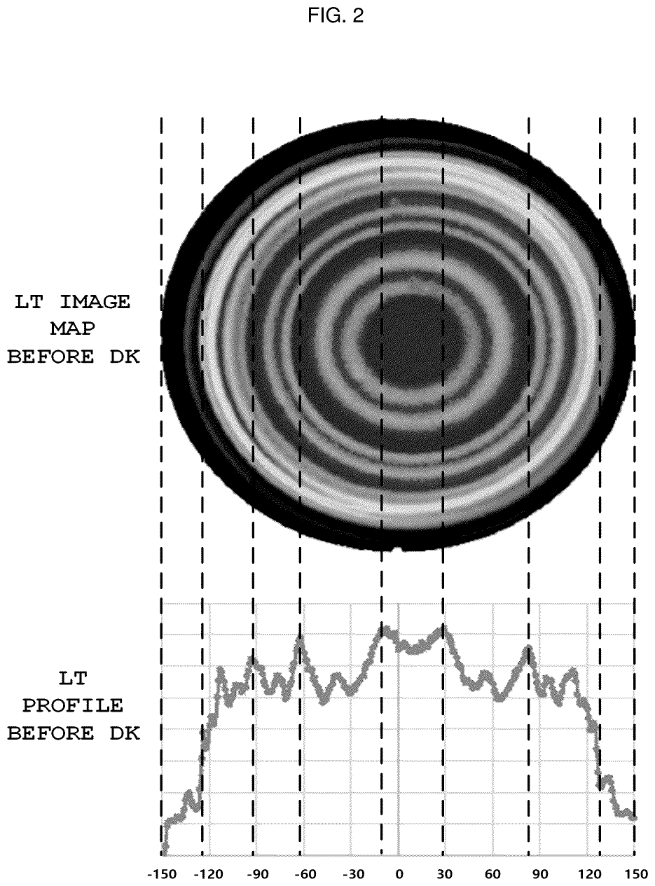

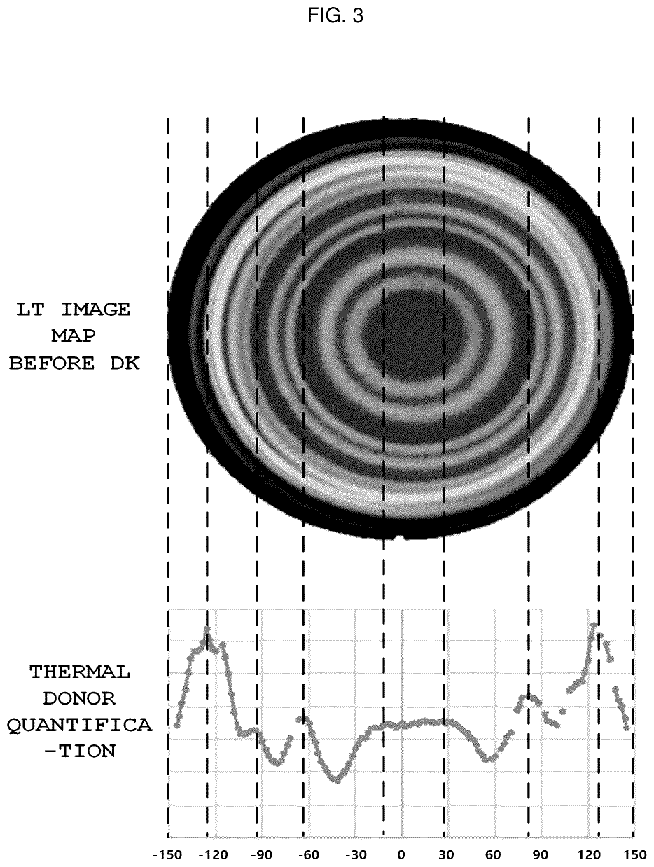

FIG. 1 is an exemplary block diagram of a thermal donor quantity prediction apparatus using the lifetime of a silicon wafer according to an embodiment, and FIGS. 2 and 3 are exemplary views illustrating the correlation between lifetime and thermal donor quantity.

As shown in FIG. 1, the thermal donor quantity prediction apparatus using the lifetime of the silicon wafer according to the embodiment mainly includes a prediction criterion data unit 100 configured to measure the lifetime and the thermal donor quantity of the same sampling wafer before and after donor killing and to compare the same to generate a correlation criterion and a thermal donor prediction unit 200 configured to acquire the lifetime of a wafer to be inspected that is selected during a wafer production process before and after donor killing and to predict the thermal donor quantity based on the correlation criterion.

At this time, the prediction criterion data unit 100 generates a correlation criterion through at least two sampling wafers 1A and 1B, which is to clarify the correlation criterion through various samples. It is desirable to provide ten or more sampling wafers 1A and 1B.

In addition, in FIG. 1, the sampling wafers are denoted by reference symbols 1A and 1B, which are intended to distinguish between before and after the donor killing process, in which heat treatment of the sampling wafers is performed at a predetermined temperature (typically about 700° C.).

The prediction criterion data unit 100 includes a donor killing portion 110 configured to perform the donor killing process, a non-contact lifetime measurement portion 120 configured to acquire the lifetime of the front surface of the sampling wafer using a microwave photoconductive attenuation method (μ-PCD method) before and after heat treatment through the donor killing portion 110, a 4PP surface resistance measurement portion 130 configured to measure a resistance value from a plurality of preset coordinate values among the coordinate values of the front surface of each of the sampling wafers 1A and 1B using a four-point probe before and after heat treatment through the donor killing portion 110, and a correlation data processing portion 140 configured to receive data measured by the non-contact lifetime measurement portion 120 and data measured by the 4PP surface resistance measurement portion 130 before and after heat treatment, to convert the received data into data according to the thermal donor quantity, and to generate correlation data.

Here, the μ-PCD method will be briefly described. In the μ-PCD method, a light pulse with energy greater than the band gap of a silicon single crystal is first irradiated to generate excess carriers in the wafer. The generated excess carriers increase conductivity of the wafer, but, over time, the excess carriers are dissipated by recombination, which decreases the conductivity. This change may be detected and interpreted as time change of reflected microwave power to obtain the recombination lifetime. The recombination lifetime is shortened if there are metal impurities or defects that form a recombination center that introduces defect levels in the forbidden band. Therefore, it is possible to evaluate metal impurities or crystal defects in the wafer through the measurement of the recombination lifetime.

In addition, the 4PP surface resistance measurement portion 130 does not measure the resistance value from the front surface of each of the sampling wafers 1A and 1B but measures the resistance value from preset specific coordinate values, which is due to the characteristics of the four-point probe and is intended to shorten the resistance value measurement time. That is, if the resistance value is measured from the front surface of each of the sampling wafers 1A and 1B, the 4PP surface resistance measurement portion 130 must be operated for a very long time, which means that it takes a long time to generate correlation data and obtain a reference value, thereby reducing the yield of the operation.

In addition, the non-contact lifetime measurement portion 120 receives the sampling wafers 1A and 1B earlier than the 4PP surface resistance measurement portion 130.

That is, the sampling wafer 1A before the donor killing process is supplied to the non-contact lifetime measurement portion 120 to measure the lifetime first, and the sampling wafer 1A is supplied to the 4PP surface resistance measurement portion 130 to measure the resistance value.

Subsequently, the sampling wafer 1B after the donor killing process is performed through the donor killing portion 110 is supplied to the non-contact lifetime measurement portion 120 to measure the lifetime after the donor killing process, and the sampling wafer 1B is supplied to the 4PP surface resistance measurement portion 130 to measure the resistance value.

This measurement process is due to the equipment characteristics of the non-contact lifetime measurement portion 120 and the 4PP surface resistance measurement portion 130.

The correlation data processing portion 140 receives the data measured by the non-contact lifetime measurement portion 120 before and after heat treatment through the donor killing portion 110, calculates the lifetime change amount, and predicts the thermal donor quantity based on the calculated lifetime change amount.

In addition, the correlation data processing portion 140 receives the data measured by the 4PP surface resistance measurement portion 130 before and after heat treatment through the donor killing portion 110, calculates the resistance value change amount, and calculates the thermal donor quantity based on the calculated resistance value change amount.

In addition, the correlation data processing portion 140 generates correlation data between the predicted thermal donor quantity based on the lifetime change amount and the calculated thermal donor quantity based on the resistance value change amount.

The reason that the correlation data can be generated will be described with reference to FIGS. 2 and 3. FIG. 2 is an exemplary view showing an image map and a profiled relationship when the lifetime (LT) is measured using the μ-PCD method before donor killing (DK) for an arbitrary mirror-finished wafer.

FIG. 3 shows thermal donor quantification obtained by a four-point probe in response to the image map when the lifetime (LT) is measured using the μ-PCD method before donor killing (DK) for the same wafer as the wafer illustrated in FIG. 2.

As can be seen from the relationship between FIGS. 2 and 3, there is a correlation between a thermal donor quantification graph obtained using a four-point probe with high reliability for the thermal donor quantity and a lifetime (LT) profile graph obtained using the μ-PCD method.

Therefore, the correlation data processing portion 140 receives the data measured by the non-contact lifetime measurement portion 120, calculates the lifetime change amount, and predicts the thermal donor quantity based on the calculated lifetime change amount.

Subsequently, the correlation data processing portion 140 receives data measured by the 4PP surface resistance measurement portion 130 before and after heat treatment through the donor killing portion 110, calculates the resistance value change amount, and calculates the thermal donor quantity based on the calculated resistance value change amount.

In addition, the correlation data processing portion 140 generates correlation data between the predicted thermal donor quantity based on the lifetime change amount and the calculated thermal donor quantity based on the resistance value change amount.

The prediction criterion data unit 100 further includes a correlation criterion generation portion 150 configured to generate a correlation function based on the correlation data generated by the correlation data processing portion 140 and a data learning processing portion 160 configured to learn based on a database constituted by the correlation data and the correlation function.

If the correlation data between the predicted thermal donor quantity based on the lifetime change amount and the calculated thermal donor quantity based on the resistance value change amount is generated so as to correspond to a plurality of preset coordinate values among coordinate values of the front surface of each of the sampling wafers 1A and 1B through the correlation data processing portion 140, the correlation criterion generation portion 150 generates a correlation function that includes the coordinate values of the front surface of each of the sampling wafers 1A and 1B based on the correlation data.

The data learning processing unit 160 is provided for optimization of the correlation function, wherein, as the prediction criterion data unit 100 is operated for a plurality of sampling wafers 1A and 1B, big data is formed and deep learning is performed to achieve optimization of the correlation function.

Once optimization of the correlation function is achieved through the process, this is applied to an actual wafer production process, which is performed by the thermal donor prediction unit 200.

The thermal donor prediction unit 200 includes a donor killing portion 210 configured to perform heat treatment at a preset temperature (about 700° C.) on arbitrary wafers 10A and 10B to be inspected upon selecting the wafers 10A and 10B to be inspected during a wafer production process, a non-contact lifetime measurement portion 220 configured to acquire the lifetime of the front surface of each of the wafers 10A and 10B to be inspected using a microwave photoconductive attenuation method (μ-PCD method) before and after heat treatment of the wafers 10A and 10B to be inspected through the donor killing portion 210, and a thermal donor quantity prediction portion 250 configured to receive the lifetime of the front surface of each of the wafers 10A and 10B to be inspected before and after heat treatment and the correlation function provided by the correlation criterion generation portion 150 and to predict the thermal donor quantity of each of the wafers 10A and 10B to be inspected.

In FIG. 1, the wafers 10A and 10B to be inspected are denoted by reference symbols 10A and 10B, which are intended to distinguish between before and after the donor killing process, in which heat treatment is performed at a predetermined temperature (typically about 700° C.) on the wafers 10A and 10B to be inspected.

In addition, the same equipment may be used as the donor killing portions denoted by reference numerals 110 and 210 in FIG. 1. Furthermore, the same equipment may be used as the non-contact lifetime measurement portions denoted by reference numerals 120 and 220 in FIG. 1.

In FIG. 1, the components are separately shown for ease of description, and therefore the components are not distinguished as first or second; however, the components may be actually distinguished from each other for convenience of a process flow.

The thermal donor quantity prediction portion 250 receives the lifetime of the front surface of each of the wafers 10A and 10B to be inspected before and after heat treatment from the non-contact lifetime measurement portion 220 from the inspection target wafer 10A and 10B, calculates the lifetime change amount, predicts the thermal donor quantity based on the calculated lifetime change amount, and corrects the predicted thermal donor quantity based on the correlation function provided by the correlation criterion generation portion 150 to finally predict the thermal donor quantity.

If the predicted thermal donor quantity exceeds a preset threshold range, the thermal donor quantity prediction portion 250 feeds back information of the predicted thermal donor quantity to the wafer production process to adjust the wafer production process.

As is apparent from the above description, a thermal donor quantity prediction method and apparatus using the lifetime of a silicon wafer according to embodiments are capable of constructing correlation data with a four-point probe and predicting the degree of generation of thermal donors in a non-destructive manner based on the correlation data, thereby reducing a decrease in production yield without wafer damage and improving thermal donor quantity prediction reliability while having high analysis capability for a front surface of a wafer.

Although the preferred embodiments have been shown and described above, the present disclosure is not limited to the above-described specific embodiments, and various modifications and variations can be made by those skilled in the art without departing from the gist of the appended claims. In addition, it is intended that such modifications and variations should not be understood independently of the technical spirit or prospect of the present disclosure.

What is claimed is:

1. A thermal donor quantity prediction method using a lifetime of a silicon wafer, the thermal donor quantity prediction method comprising:
measuring a lifetime and a thermal donor quantity of a sampling wafer before and after donor killing and comparing the same to acquire correlation data; and
acquiring the lifetime of a wafer to be inspected that is selected during a wafer production process before and after donor killing and predicting the thermal donor quantity based on the correlation data.

2. The thermal donor quantity prediction method according to claim 1, further comprising feeding back information of the predicted thermal donor quantity to the wafer production process to adjust the wafer production process if the predicted thermal donor quantity exceeds a preset threshold range.

3. The thermal donor quantity prediction method according to claim 1, wherein the acquisition step comprises:
a step of providing the sampling wafer;
a first measurement step of measuring the lifetime and a resistance value of the sampling wafer before donor killing;
a second measurement step of measuring the lifetime and the resistance value of the sampling wafer after donor killing;
a step of calculating the thermal donor quantity based on an amount of change in the lifetime measured in the first measurement step and the second measurement step and the measured resistance value; and
a step of comparing the lifetime change amount with the thermal donor quantity to generate correlation data.

4. The thermal donor quantity prediction method according to claim 3, wherein the first measurement step comprises:
a step of generating a first lifetime image map of a front surface of the sampling wafer before the donor killing;
a first profiling step of profiling a lifetime corresponding to coordinate values of the front surface of the sampling wafer based on the first lifetime image map; and
a first resistance value measurement step of measuring a resistance from a plurality of preset coordinate values among the coordinate values of the front surface of the sampling wafer before the donor killing.

5. The thermal donor quantity prediction method according to claim 4, wherein the second measurement step comprises:
a step of generating a second lifetime image map of the front surface of the sampling wafer after the donor killing;
a second profiling step of profiling a lifetime corresponding to the coordinate values of the front surface of the sampling wafer based on the second lifetime image map; and
a second resistance value measurement step of measuring the resistance from the plurality of preset coordinate values among the coordinate values of the front surface of the sampling wafer after the donor killing.

6. The thermal donor quantity prediction method according to claim 5, wherein the sampling wafer used in the first measurement step and the sampling wafer used in the second measurement step are the same.

7. The thermal donor quantity prediction method according to claim 5, wherein the step of generating the correlation data comprises:
predicting the thermal donor quantity according to the lifetime change amount from the plurality of the same preset coordinate values; and
comparing the predicted thermal donor quantity with the acquired thermal donor quantity to obtain the correlation data.

8. The thermal donor quantity prediction method according to claim 7, further comprising:
generating a correlation function between the predicted thermal donor quantity and the acquired thermal donor quantity based on the correlation data from the plurality of the same preset coordinate values after the step of generating the correlation data, wherein
upon predicting the thermal donor quantity, the correlation function is provided as a criterion for correcting the predicted thermal donor quantity.

9. The thermal donor quantity prediction method according to claim 1, wherein the prediction step comprises:
selecting an arbitrary wafer to be inspected during the wafer production process;
acquiring a lifetime of the wafer to be inspected before and after donor killing;
calculating a lifetime change amount based on the acquired lifetime;
calculating a thermal donor quantity according to the lifetime change amount; and
correcting the calculated thermal donor quantity based on a correlation function to estimate the thermal donor quantity.

10. A computer-readable recording medium having a program for performing the thermal donor quantity prediction method according to claim 1 recorded therein.

11. A thermal donor quantity prediction apparatus using a lifetime of a silicon wafer, the thermal donor quantity prediction apparatus comprising:
a prediction criterion data unit configured to measure a lifetime and a thermal donor quantity of a sampling wafer before and after donor killing and to compare the same to acquire correlation criterion; and
a thermal donor prediction unit configured to acquire the lifetime of a wafer to be inspected that is selected during a wafer production process before and after donor killing and to predict the thermal donor quantity based on the correlation criterion.

12. The thermal donor quantity prediction method according to claim 11, wherein the thermal donor prediction unit feeds back information of the predicted thermal donor quantity to the wafer production process to adjust the wafer production process if the predicted thermal donor quantity exceeds a preset threshold range.

13. The thermal donor quantity prediction method according to claim 11, wherein the prediction criterion data unit comprises:
a first donor killing portion configured to perform heat treatment on the sampling wafer at a preset temperature;
a first non-contact lifetime measurement portion configured to acquire a lifetime of a front surface of the sampling wafer before and after heat treatment through the first donor killing portion;
a surface resistance measurement portion configured to measure a resistance value from a plurality of preset coordinate values among coordinate values of the front surface of the sampling wafer before and after heat treatment through the donor killing portion; and
a correlation data processing portion configured to receive data measured by the first non-contact lifetime measurement portion and data measured by the surface resistance measurement portion before and after the heat treatment, to convert the received data into data according to the thermal donor quantity, and to generate correlation data.

14. The thermal donor quantity prediction method according to claim 13, wherein the sampling wafer used by the surface resistance measurement portion and the sampling wafer used by the first non-contact lifetime measurement portion are the same.

15. The thermal donor quantity prediction method according to claim 13, wherein the prediction criterion data unit further comprises a correlation criterion generation portion configured to generate a correlation function based on the correlation data.

16. The thermal donor quantity prediction method according to claim 15, wherein the prediction criterion data unit further comprises a data learning processing portion configured to learn based on a database constituted by the correlation data and the correlation function.

17. The thermal donor quantity prediction method according to claim 16, wherein the correlation data processing portion is configured:
to receive the data measured by the first non-contact lifetime measurement portion before and after the heat treatment, to calculate a lifetime change amount, and to predict the thermal donor quantity based on the calculated lifetime change amount;
to receive the data measured by the surface resistance measurement portion before and after the heat treatment, to calculate a resistance value change amount, and to calculate the thermal donor quantity based on the calculated resistance value change amount; and
to generate correlation data between the predicted thermal donor quantity based on the lifetime change amount and the calculated thermal donor quantity based on the resistance value change amount.

18. The thermal donor quantity prediction method according to claim 17, wherein, if the correlation data between the predicted thermal donor quantity based on the lifetime change amount and the calculated thermal donor quantity based on the resistance value change amount is generated so as to correspond to a plurality of preset coordinate values among coordinate values of the front surface of the sampling wafer through the correlation data processing portion, the correlation criterion generation portion generates a correlation function that comprises the coordinate values of the front surface of the sampling wafer based on the correlation data.

19. The thermal donor quantity prediction method according to claim 18, wherein the thermal donor prediction unit comprises:
a second donor killing portion configured to perform heat treatment on an arbitrary wafer to be inspected at a preset temperature upon selecting the wafer to be inspected during a wafer production process;
a second non-contact lifetime measurement portion configured to acquire a lifetime of a front surface of the wafer to be inspected before and after heat treatment through the second donor killing portion; and
a thermal donor quantity prediction portion configured to receive the lifetime of the front surface of the wafer to be inspected before and after the heat treatment and the correlation function and to predict the thermal donor quantity of the wafer to be inspected.

20. The thermal donor quantity prediction method according to claim 18, wherein the thermal donor quantity prediction portion receives the lifetime of the front surface of the wafer to be inspected before and after the heat treatment, calculates a lifetime change amount, predicts the thermal donor quantity based on the calculated lifetime change amount, and corrects the predicted thermal donor quantity based on the correlation function to finally predict the thermal donor quantity.
